(19) United States
(12) Patent Application Publication
(10) Pub. No.: US 2025/0271215 A1
(43) Pub. Date: Aug. 28, 2025

(54) OVEN WITH ADJUSTABLE VOLUME PROCESSING CHAMBER

(71) Applicant: Yield Engineering Systems, Inc., Fremont, CA (US)

(72) Inventors: Alvin Lin, Cupertino, CA (US); Xinxuan Tan, Milpitas, CA (US); Taylor Nguyen, Milpitas, CA (US); Terry Pederson, Sunnyvale, CA (US); Lei Jing, Fremont, CA (US); Tapani Laaksonen, Fremont, CA (US); Christopher Lane, Los Gatos, CA (US); Laxman Murugesh, Livermore, CA (US)

(73) Assignee: Yield Engineering Systems, Inc., Fremont, CA (US)

(21) Appl. No.: 18/586,131

(22) Filed: Feb. 23, 2024

(51) Int. Cl. F27B 17/00; B23K 3/04; H01L 23/00

(52) U.S. Cl. CPC F27B 17/0025; B23K 3/04; H01L 24/75; H01L 2224/75283

(57) ABSTRACT

An oven with a processing chamber having an adjustable enclosed volume that is configured to support a substrate and includes a lamp assembly configured to heat the substrate. The oven also includes a sealing door that bounds one end of the processing chamber. The sealing door is configured to be moved from a first position to a second position to change the enclosed volume of the processing chamber from a first volume to a second volume.

### TECHNICAL FIELD

The present disclosure relates to an oven with a processing chamber having an adjustable enclosed volume.

### BACKGROUND

The electronics industry has continued to engineer greater functionality into smaller electronic devices at lower cost. This drive towards smaller and less expensive electronic devices has driven the development of advanced semiconductor packaging technologies. For example, wire bonds conventionally used to attach a die to a substrate, have been replaced by solder bumps. Flip chip, also known as controlled collapse chip connection (abbreviated as C4), is one such method of connecting semiconductor dies (or IC chips) to a substrate with solder bumps deposited on the I/O (input/output) pads of the dies on the top side of the wafer before the wafer is diced into individual dies. After the wafer is diced into individual dies, the die is flipped so that its top side faces down and aligned so that its pads align with matching pads on the substrate. The solder is reflowed to complete the interconnect.

Conventionally, solder reflow is accomplished by passing the assembly through a batch reflow oven in which the assembly passes through different zones of the oven on a conveyor belt. The zones heat and cool the wafers and introduce chemical vapor to the wafers at atmospheric pressure. Atmospheric pressure may provide a competing force to the chemical vapor pressure and hinder the vapor from reaching all regions of the solder bumps. Moreover, conventional reflow systems may require a relatively large amount of chemicals and, as a result, increase the cost of ownership and operation. The possibility of chamber contamination may also be high resulting in more frequent cleaning and maintenance requirements. The configurable ovens of the current disclosure may alleviate one or more of the above-described issues.

### SUMMARY

Several embodiments of a processing oven having an adjustable enclosed volume is disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one embodiment, an oven is disclosed. The oven may include a processing chamber having an adjustable enclosed volume. The processing chamber may include a spindle configured to support a substrate. The oven may also include a lamp assembly configured to heat the substrate supported on the spindle. The lamp assembly may include a plurality of spaced-apart lamps. The oven may further include a sealing door that bounds one end of the processing chamber. The sealing door may be configured to be moved from a first position to a second position to change the enclosed volume of the processing chamber from a first volume to a second volume.

Various embodiments of the disclosed oven may alternatively or additionally include one or more of the following features: the second volume may be between about 25%-75% of the first volume; the second volume may be less than 50% of the first volume; the sealing door may bound a bottom end of the processing chamber and the lamp assembly may be positioned at a top end of the processing chamber; the spindle may be configured to rotate with the substrate about a central axis of the processing chamber; the substrate may be positioned closer to the lamp assembly when the sealing door is located in the second position than when the sealing door is located in the first position; the oven may further include a chemical delivery tube positioned in processing chamber and the chemical delivery tube may include multiple spaced-apart ports configured to discharge a gas into the processing chamber; a distance of the chemical delivery tube from a top end of the processing chamber may be substantially same as the distance of the substrate from the top end when the sealing door is located in the second position; the chemical delivery tube may be positioned radially outwards of an outer periphery of the substrate and radially inwards of a side wall of the processing chamber; the chemical delivery tube may have an arc-shape and subtend a sector angle between about 70-1200 about a central axis of the processing chamber; the sector angle may be about 900; the processing chamber may include a lid and the lamp assembly may be disposed on an underside of the lid; a side wall of the processing chamber may include a substrate-inlet port configured to direct the substrate into the enclosed volume of the processing chamber; the substrate-inlet port may be positioned above the sealing door when the sealing door is located in the first position, and may be positioned below the sealing door when the sealing door is located in the second position.

In another embodiment, an oven is disclosed. The oven may include a processing chamber having an adjustable enclosed volume, a lamp assembly at a top end of the processing chamber, and a sealing door at a bottom end of the processing chamber. The processing chamber may be configured to support a substrate and the lamp assembly may include a plurality of spaced-apart lamps configured to heat the substrate. The sealing door may be configured to be moved from a first position to a second position to decrease the enclosed volume of the processing chamber from a first volume to a second volume. The second volume may be between about 25%-75% of the first volume.

In a further embodiment, a method of processing a substrate in an oven is disclosed. The method may include loading the substrate on a spindle positioned in a processing chamber of the oven. The processing chamber may have an adjustable enclosed volume bounded by a sealing door located at one end of the processing chamber. The method may also include moving the sealing door from a first position to a second position to change the enclosed volume of the processing chamber from a first volume to a second volume. The method may further include activating a lamp assembly of the oven to heat the substrate, wherein the lamp assembly includes a plurality of spaced-apart lamps.

Various embodiments of the disclosed method may alternatively or additionally include one or more of the following features: the second volume may be between about 25%-75% of the first volume; the second volume may be less than 50% of the first volume; the sealing door may bound a bottom end of the processing chamber and the lamp assembly may be positioned at a top end of the processing chamber; rotating the spindle with the substrate about a central axis of the processing chamber; the substrate may be positioned closer to the lamp assembly when the sealing door is located in the second position than when the sealing door is located in the first position; discharging a gas into the processing chamber via multiple spaced-apart ports of a chemical delivery tube positioned in processing chamber; a distance of the chemical delivery tube from a top end of the processing chamber may be substantially same as the distance of the substrate from the top end when the sealing door is located in the second position; the chemical delivery tube may be positioned radially outwards of an outer periphery of the substrate and radially inwards of a side wall of the processing chamber; the chemical delivery tube may have an arc-shape and subtend a sector angle between about 70-1200 about a central axis of the processing chamber; the sector angle may be about 900; the processing chamber may include a lid and the lamp assembly may be disposed on an underside of the lid; a side wall of the processing chamber may include a substrate-inlet port configured to direct the substrate into the enclosed volume of the processing chamber; the substrate-inlet port may be positioned above the sealing door when the sealing door is located in the first position, and may be positioned below the sealing door when the sealing door is located in the second position.

### BRIEF DESCRIPTION OF THE DRAWINGS

The accompanying drawings, which are incorporated in and constitute a part of this disclosure, illustrate exemplary embodiments and, together with the description, are used to explain the disclosed principles. In these drawings, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing proportional relationships between different features in a figure. Additionally, even if it is not specifically mentioned, aspects described with reference to one embodiment or figure may also be applicable to, and may be used with, other embodiments or figures.

FIGS. 1A and 1B illustrate an exemplary oven of the current disclosure;

FIG. 2 illustrates an exemplary substrate configured to processed in the oven of FIG. 1A;

FIG. 3 illustrates an exemplary temperature profile that may be used to process the substrate of FIG. 2;

FIG. 4 illustrates an exemplary spindle of the oven of FIG. 1A;

FIGS. 5A and 5B are schematic side views of the processing chamber of the oven of FIG. 1A;

FIG. 6 illustrates a perspective view of an exemplary oven with its lid open;

FIG. 7 is a flow chart of an exemplary process that may be carried out in the oven of FIG. 1A;

FIG. 8A is perspective view showing a portion of an exemplary processing chamber of the oven of FIG. 1A;

FIG. 8B is a schematic top view of an exemplary processing chamber of the oven of FIG. 1A;

FIGS. 9A-9B are schematic diagrams illustrating some exemplary ovens of the current disclosure; and

FIG. 10 is a schematic diagram illustrating another exemplary oven of the current disclosure.

### DETAILED DESCRIPTION

All relative terms such as “about,” “substantially,” “approximately,” etc., indicate a possible variation of ±10% (unless noted otherwise or another variation is specified). For example, a feature disclosed as being about “t” units long (wide, thick, etc.) may vary in length from (t−0.1t) to (t+0.1t) units. Similarly, a temperature within a range of about 100-150° C. can be any temperature between (100−10%) and (150+10%). In some cases, the specification also provides context to some of the relative terms used. Similarly, term “generally” implies a degree of approximation or similarity rather than an exact replication. For example, a structure described as being substantially circular or generally circular, it means that the structure shares similarities with the geometric characteristics of a circle but may not precisely match its form. For example, its shape may deviate slightly (e.g., 10% variation in diameter or curvature at different locations, etc.) from being perfectly circular. Further, a range described as varying from, or between, 5 to 10 (5-10), includes the endpoints (i.e., 5 and 10).

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

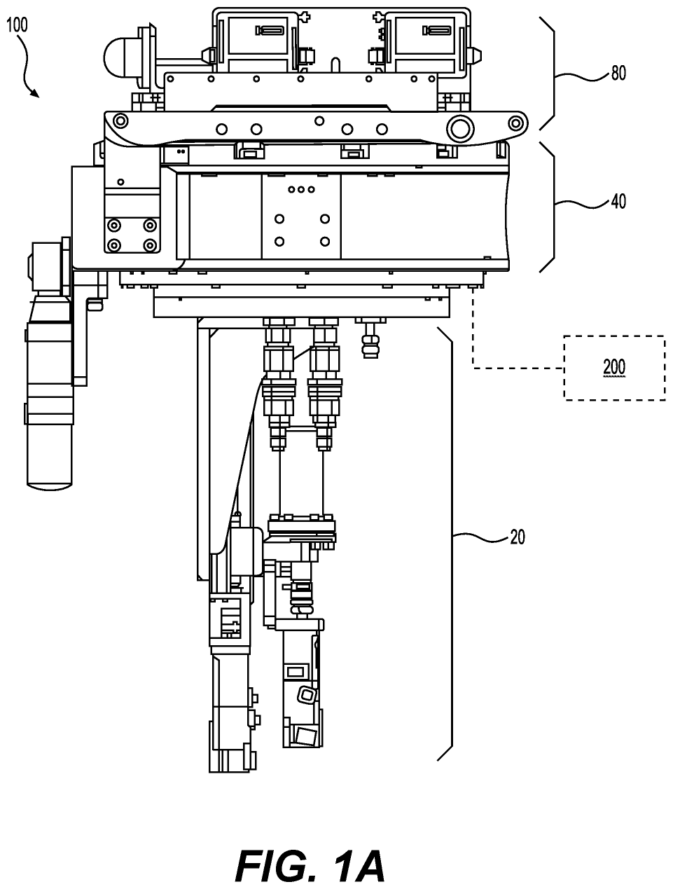

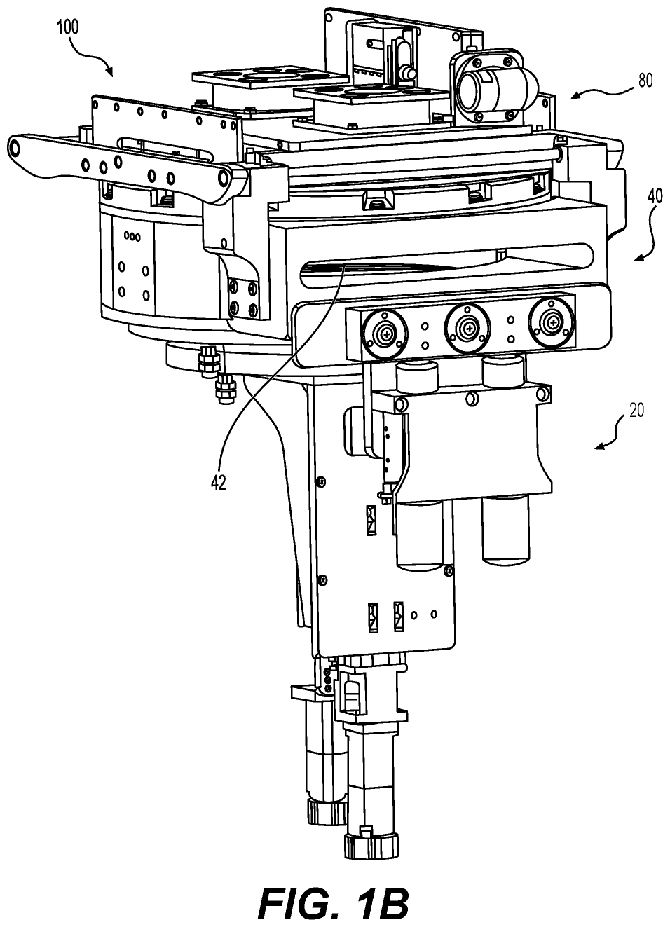

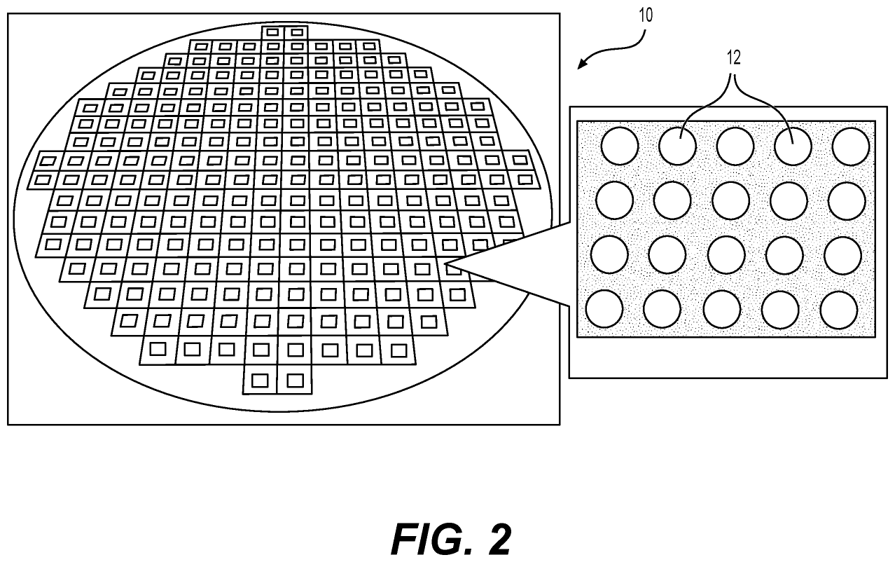

FIG. 1A is a side view and FIG. 1B is a perspective view of an exemplary processing oven 100 of the current disclosure. In the discussion below, processing oven 100 will be described with reference to an exemplary use case, for example, as a solder reflow oven. However, this use case is only exemplary, and oven 100 can be used for any high temperature (e.g., curing polymers, etc.) application. Oven 100 includes a processing chamber 40 configured to receive one or more substrates (e.g., wafer, organic/ceramic substrates, semiconductor packages, printed circuit board (PCB), etc.) and subject the substrates to a high temperature process. In the discussion below, a semiconductor wafer with solder on its top surface (see FIG. 2) will be described as the substate that is subject to an exemplary solder reflow process in oven 100. In general, any size (e.g., 200 mm, 300 mm, etc.) of semiconductor wafer may be received in chamber 40. FIG. 2 illustrates an exemplary semiconductor wafer 10 that may be received in chamber 40 and subject to a reflow process. As would be recognized by a person skilled in the art, after integrated circuit processing, wafer 10 includes multiple dies (or IC chips), and solder material may be deposited on the I/O pads of the multiple dies in wafer 10. Prior to dicing the wafer 10 into individual dies, wafer 10 may be subject to a reflow process in oven 100 to form solder bumps 12 thereon (called wafer bumping). Any type of solder material (lead-free solder, lead-tin solder, etc.) may be deposited on wafer 10 and the wafer 10 may be subject to any type of reflow process or reflow profile. Persons having ordinary skill in the art would recognize that reflow process that wafer 10 is subjected to depends on the type of solder material deposited on wafer 10. Suitable reflow profiles for different types of solder materials are available in the published literature and may be obtained from solder vendors. FIG. 3 illustrates an exemplary reflow profile that may be applied to wafer 10 in chamber 40. In FIG. 3, the X-axis shows time in seconds, and the Y-axis shows temperature in degrees Celsius (° C.).

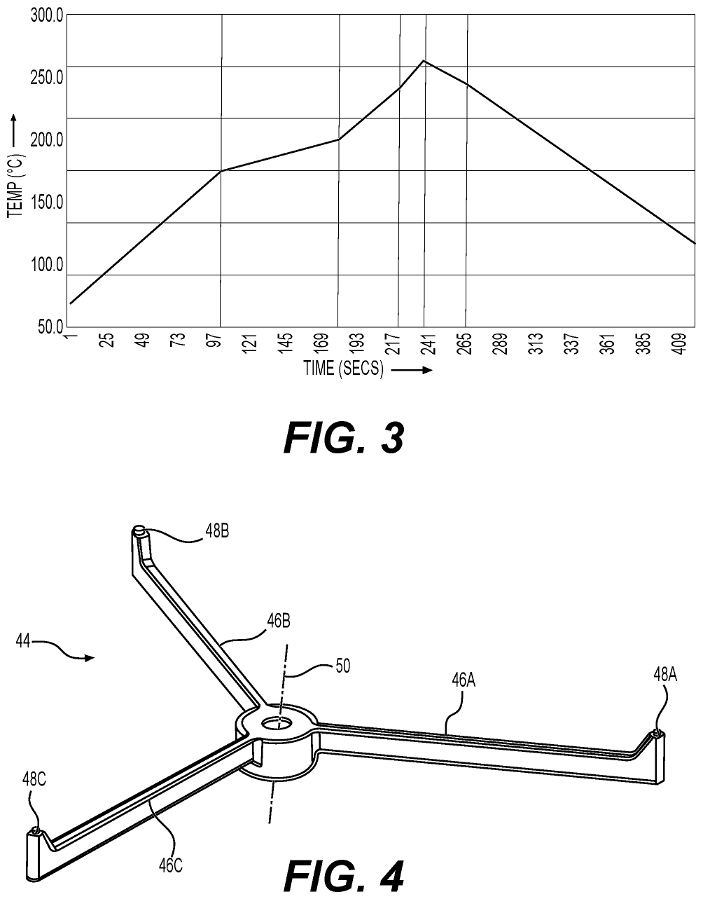

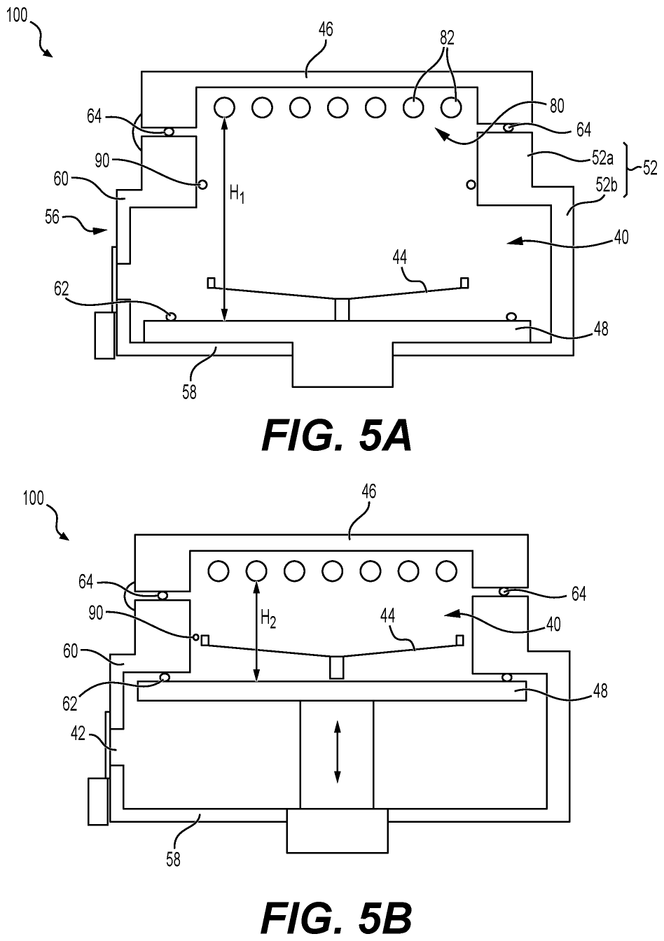

FIGS. 5A and 5B are schematic illustrations of an exemplary chamber 40 of oven 100. A robotic manipulator or arm (not shown) may insert wafer 10 into chamber 40 through an inlet port 42 (see FIG. 1B). Wafer 10 may be disposed on a spindle 44 within chamber 40. FIG. 4 illustrates an exemplary spindle 44 separated from oven 100. With specific reference to FIG. 4, spindle 44 may include a plurality of arms 46A, 46B, 46C (e.g., 3 arms in the embodiment of FIG. 4) that extend radially outward from a central axis 50 of chamber 40. Each arm 46A, 46B, 46C of spindle 44 includes nub 48A, 48B, 48C that projects upwards. Wafer 10 may rest on nubs 48A, 48B, 48C of spindle 44. Oven 100 also includes a motor assembly 20 (see FIGS. 1A-1B) that may be configured to support and control the movement of wafer 10 in chamber 40. In some embodiments, motor assembly 20 may include one or motors configured to rotate spindle 44 (and wafer 10 supported thereon) in chamber 40 about its central axis 50. Spindle 44 may be rotated at any speed. In some embodiments, the rotational speed of spindle 44 may vary between about 0-20 RPM. Motor assembly 20 may also include one or more motors to raise and lower the rotating spindle 44 and/or other components (e.g., sealable door 48) of oven 100 within chamber 40 along axis 50.

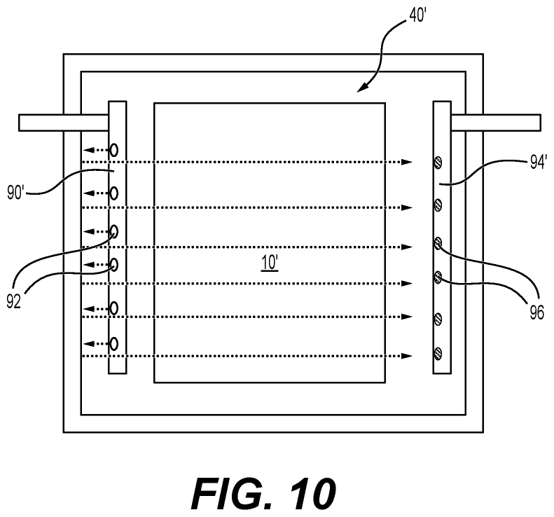

In some embodiments, chamber 40 may have a substantially cylindrical configuration (see FIG. 1B). However, a substantially cylindrical shape is not a requirement. In general, chamber 40 can have any shape (see, e.g., FIG. 10). In some embodiments, the chamber 40 may be substantially square, substantially rectangular, or have another shape. With specific reference to FIGS. 5A-5B, chamber 40 may have an enclosed volume bounded (or defined) by a top wall or lid 46, a bottom wall or sealing door 48, and a side wall 52 extending between lid 46 and door 48. In some embodiments, lid 46 may be hinged on side wall 52 and configured to rotate about the hinge between an open position and a closed position. When lid 46 is closed, an O-ring 64 or another sealing device between lid 46 and side wall 52 may seal the enclosed volume of chamber 40 from the outside atmosphere. Side wall 52 of chamber 40 defines a slit or an opening that forms inlet port 42 (see FIG. 1B). In some embodiments, a valve, flap, or another closing mechanism may seal the opening of inlet port 42 such that the enclosed volume of chamber 40 can be pumped down to a low pressure.

Oven 100 may include a lamp assembly 80 including a plurality of lamps 82 configured to heat wafer 10 positioned in chamber 40. In some embodiments, lamp assembly 80 may be positioned within chamber 40 and configured to heat the top surface of wafer 10 positioned in chamber 40. In some embodiments, lamps 82 of lamp assembly 80 may be arranged on, or coupled to, the underside of lid 46 such that the lamp assembly swivels about the hinge along with the lid. When activated, the lamps 82 of lamp assembly 80 heats the top surface of wafer 10 in chamber 40. In general, lamp assembly 80 may include any number and any type of lamps 82. In some embodiments, lamp assembly 80 may include 4-10 infrared (IR) lamps having a power between about 1-10 kW for each lamp, or between about 1.5-3 kW (or about 2 kW) for each lamp 82. In some embodiments, lamp assembly 80 may include seven halogen lamps 82. The lamps 82 may be arranged (e.g., spaced apart) such that they evenly heat the top surface of wafer 10 in chamber 40. Details of the lamp assembly and oven 100 in some exemplary embodiments of the current disclosure are described in U.S. Pat. No. 11,296,049 incorporated by reference in its entirety herein.

The size (e.g., width, diameter, etc.) of chamber 40 depends upon the application, for example, the size of wafer 10 that will be processed in chamber 40. In some embodiments, a chamber 40 configured to process 300 mm wafers may have a diameter of about 450 mm. However, this size is only exemplary, and chamber 40 may have any size. Ovens of the current disclosure are configured such that the height of chamber 40 (and consequently the enclosed volume of the chamber) may be adjusted (e.g., varied or changed). In some embodiments, the height of chamber 40 (and consequently its volume) may be changed by raising and lowering sealing door 48 that forms the bottom wall of chamber 40. FIG. 5A illustrates a configuration of oven 100 with sealing door 48 disposed at its lower position (or a first position) and FIG. 5B illustrates a configuration of oven 100 with sealing door 48 disposed at its upper position (or a second position). The sealing door 48 may be moved between its lower and upper positions (i.e., first and second positions) by a motor of motor assembly 80. As illustrated in FIGS. 5A and 5B, the height and enclosed volume of chamber 40 is smaller when sealing door 48 is located in its upper position and larger when sealing door 48 is located in its lower position. In some embodiments, the enclosed volume of chamber 40 when sealing door 48 is located in its upper position may be between about 25%-75% of its enclosed volume when sealing door 48 is located in its lower position. In some embodiments, the enclosed volume of chamber 40 when sealing door 48 is located in its upper position may be between about 40%-60% of its enclosed volume when sealing door 48 is located in its lower position. In some embodiments, the enclosed volume of chamber 40 may be more than 50% smaller when sealing door 48 is located in its upper position than when sealing door 48 is located in its lower position.

The values of chamber height when sealing door 48 is positioned in the upper and lower positions depend on the application (e.g., process carried out, number of samples being treated, etc.). In some exemplary embodiments, the height “H₁” of chamber 40 (e.g., the distance between the top surface of sealing door 48 and the bottom surface of lamp assembly 80) when sealing door 48 is in the lower position is between about 75-150 mm and the height “H₂” of chamber 40 when sealing door 48 is in the upper position is between about 20-50 mm. It should be noted that these heights are merely exemplary, and in general, these heights may have any values. In some embodiments, the distance between the top surface of wafer 10 seated on spindle 44 and the underside of lamp assembly 10 may be between about 10-50 mm when sealing door 48 is at its upper position (see FIG. 5B), and between about 75-150 mm when sealing door 48 is at its lower position (see FIG. 5A). In some embodiments, this distance may be between about 20-30 mm when sealing door 48 is at its upper position, and about 90-120 mm when sealing door 48 is at its lower position.

In some embodiments, in addition to sealing door 48, spindle 44 may also be configured to move vertically up and down along central axis 50. A motor of motor assembly 20 may be configured to move the rotating spindle 44 (along wafer 10 supported thereon) vertically along central axis 50. For example, when sealing door 48 is located at its lower or upper position, spindle 44 may move wafer 10 towards or away from lamp assembly 80. In other words, in some embodiments of oven 100, both sealing door 48 and spindle 44 may be individually configured to move wafer 10 towards and away from lamp assembly 80. However, this is only exemplary, and in some embodiments of oven 100, spindle 44 may not be configured to move along central axis 50 independent from sealable door 48. In such embodiments, only sealing door 48 may be configured to move wafer 10 towards and away from lamp assembly 80, and spindle 44 may move up and down along with sealing door 48. When sealing door 48 is located at its upper position, wafer 10 (on spindle 44) may be positioned closer to lamp assembly 80 than when sealing door 48 is positioned at its lower position.

It should be noted that although sealing door 48 is described as having two positions (e.g., a lower and an upper position) to adjust the enclosed volume of chamber 40 between two values (e.g., a lower volume and a higher volume), this is only exemplary. In some embodiments, sealing door 48 may be moved and fixed at more than two positions (e.g., three, four, five, etc.) to create corresponding changes in the enclosed volume of chamber 40. In general, sealing door 48 may be moved and fixed (or located) at multiple positions vertically spaced apart from each other to produce corresponding changes in the enclosed volume of chamber 40. For example, in addition to the lower and upper (or first and second) positions illustrated in FIGS. 5A and 5B, sealing door 48 may also be moved and fixed at one or more locations between these two positions to result in chamber 40 having multiple enclosed volumes.

Sealing door 48 may be moved vertically up and down to selectively define multiple enclosed volumes (e.g., a smaller volume and a larger volume in the embodiment of FIGS. 5A and 5B) of chamber 40 in any manner. In some embodiments, as illustrated in FIGS. 5A and 5B, side wall 52 of chamber 40 may include an upper portion 52A and a lower portion 52B that is larger in size (e.g., diameter, width, etc.) than upper portion 52A. The top end of the upper portion 52A may be covered by lid 46 and the bottom end of the upper portion 52A may be connected to the top end of the lower portion 52B at a ledge 60. And the bottom end of the lower portion 52B may be covered by a bottom wall 58. A housing 56 may be defined by lid 46 and bottom wall 58 positioned on opposite sides of side wall 52. Sealing door 48 may be configured to move vertically up and down in the lower portion 52B of side wall 52 between ledge 60 and bottom wall 58. In its lower position, sealing door 48 may be positioned proximate (or mate with) bottom wall 58 to define the larger enclosed volume of chamber 40. When sealing door 48 is moved to its upper position, it may mate with ledge 60 to reduce the enclosed volume of chamber 40. An O-ring 62 positioned between the bottom surface of ledge 60 and the top surface of sealing door 48 may seal the reduced enclosed volume of chamber 40 from the outside atmosphere.

In some embodiments, inlet port 42 through which wafer 10 is inserted into chamber 40 may be located on housing 56 in lower portion 52B of side wall 52 such that, when sealing door 48 is located at its upper position, the inlet port is positioned below the sealing door (see FIG. 5B), and therefore, fluidly decoupled from the enclosed volume of chamber 40. In contrast, when sealing door 48 is located at its lower position (see FIG. 5A), the inlet port is positioned above the sealing door and therefore fluidly coupled to the enclosed volume of chamber 40. It should be noted that the above-described configuration is only exemplary, and ovens of the current disclosure may have other configurations.

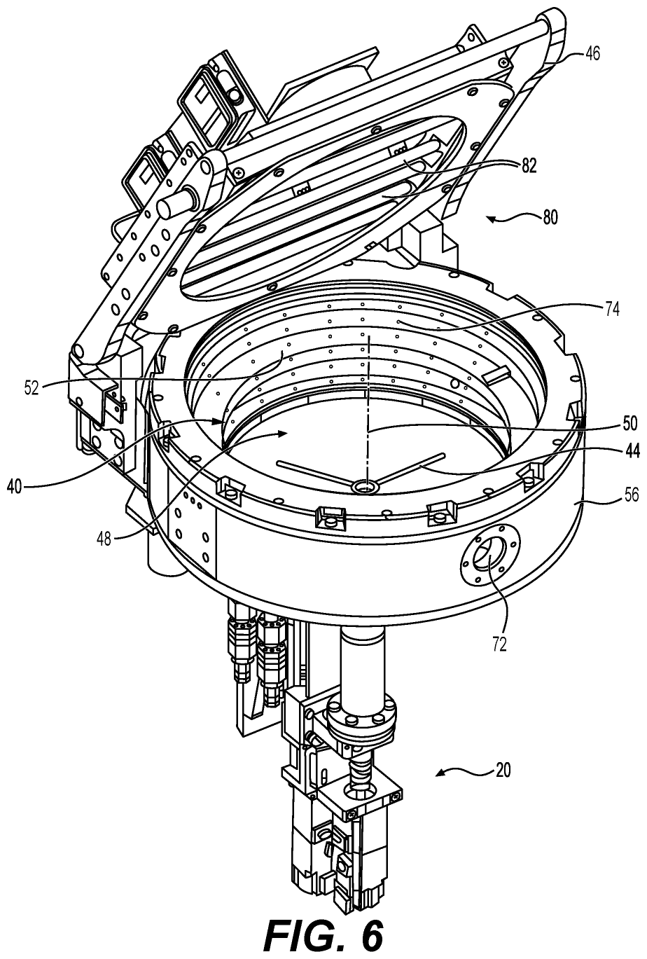

FIG. 6 illustrates a perspective view of an exemplary oven 100 with its lid 46 in an open position. Housing 56 of oven 100 may include one or more gas ports 72. Although only one gas port 72 is shown in FIG. 6, in some embodiments, housing 56 may include multiple gas ports 72. Process gas or an inert gas (e.g., nitrogen gas) may be selectively directed into chamber 40 through these gas port 72. In some embodiments, vacuum pump may be coupled to one or more gas port 72 to generate a vacuum in chamber 40. In some embodiments, side wall 52 of chamber 40 may include multiple openings (e.g., gas inlet ports 74) configured to direct process gas and/or inert gas into (or exhaust the gas from) chamber 40. In the embodiment of FIG. 6, lamps 82 of lamp assembly 80 are positioned on the underside of lid 46. In some embodiments, lamps 82 may be arranged closer together at the edges (of lid 46) than at the center. As a result of edge effects, wafer 10 in chamber 40 may cool down quicker at the edges than at the center. A smaller relative spacing of lamps 82 at the edges than at the center may assist in achieving an even temperature distribution on wafer 10.

In some embodiments, lamps 82 may be controlled by control system 200 (schematically illustrated in FIG. 1A) of oven 100 to heat wafer 10 in chamber 40 to a desired temperature at a selected temperature ramp rate. For example, a different number of lamps 82 may be activated to increase or decrease the temperature and/or the ramp rate. Alternatively, or additionally, in some embodiments, the power of lamps 82 may be varied to vary the temperature and/or the ramp rate. In some embodiments, control system 200 may control the power to lamps 82 based on the detected temperature in chamber 40 (e.g., using a feedback loop). For example, when thermocouples (or pyrometers or another temperature detection sensor) in chamber 40 indicate that the temperature of wafer 10 is below a desired value, the control system 200 may increase the power to lamps 82. In some embodiments, when the thermocouples indicate that the temperature variation in wafer 10 is above a threshold value (e.g., temperature at the edges of the wafer is below the temperature at the center, etc.), control system 200 may vary the power to different lamps 82 in lamp assembly 80. Although not visible in FIG. 6, in some embodiments, a transparent window (e.g., made of a material that is transparent to the wavelength of light emanating from lamps 82) may be provided at the bottom of lamp assembly 80 to isolate and protect lamps 82 from the environment within chamber 40. In such embodiments, lamps 82 heat the wafer in chamber 40 through the transparent window. In some embodiments, the window may be made of, for example, quartz, glass, etc.

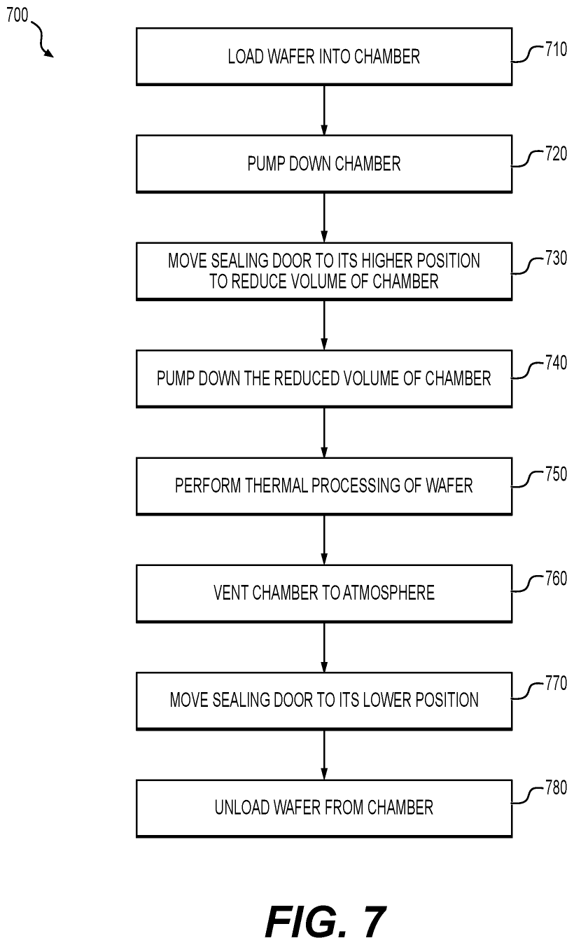

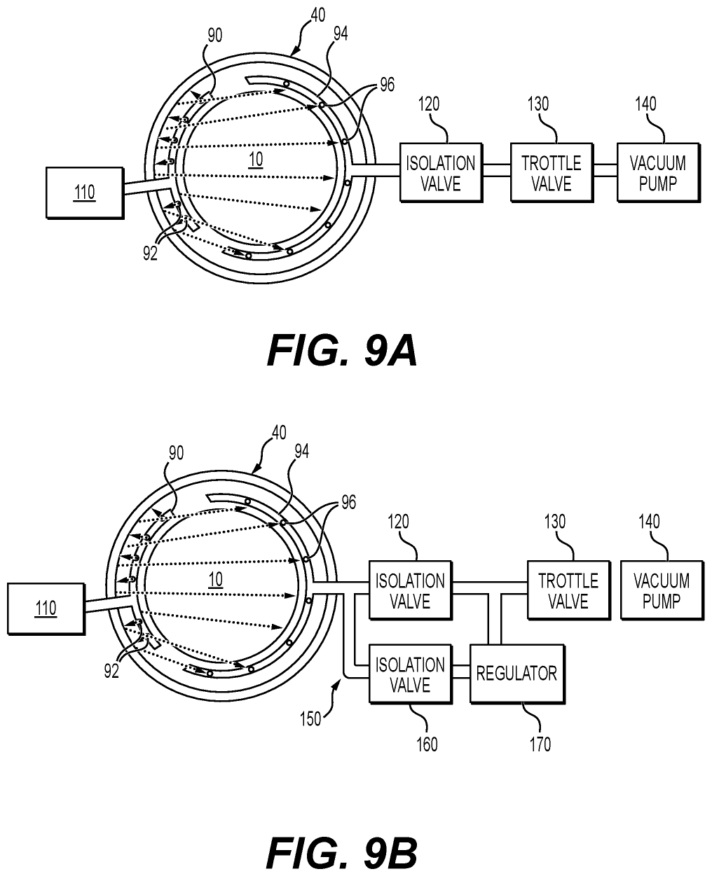

An exemplary process 700 using oven 100 will now be described with reference to FIG. 7. In step 710, a wafer (e.g., wafer 10 of FIG. 2) may be loaded into chamber 40 of oven 100. When the wafer is loaded, sealing door 48 of oven 10 may be located at its lower position (as illustrated in FIG. 5A) such that chamber 40 has a larger enclosed volume and spindle 44 is accessible via inlet port 42. Wafer 10 may be inserted into chamber 40 through inlet port 42 and positioned on nubs 48A-48D of spindle 44 (see FIG. 4). In some embodiments, in step 710, inlet port 42 is opened, wafer 10 is inserted into the chamber through the open inlet port and positioned on spindle 44, and inlet port 42 is then closed. In step 720, chamber 40 with the loaded wafer may be pumped down in pressure. In general, in this step, the pressure in chamber 40 may be pumped down to any value of pressure below atmospheric pressure. Chamber 40 may be pumped down to a sub-atmospheric pressure using vacuum pump 140 (see FIGS. 9A-9B). In some embodiments, chamber 40 may be pumped down to a pressure between about 100 milliTorr-100 Torr in this step.

In step 730, the sealing door 48 may be moved (e.g., translated) to its upper position to reduce the enclosed volume of chamber 40 (see FIG. 5B). The sealing door 48 may be moved to its upper position by activating a motor of motor assembly 20. When the sealing door 48 is positioned in its upper position, the enclosed volume of chamber 40 is reduced and decoupled from inlet port 42. In step 740, the reduced enclosed volume of the chamber 40 is pumped down to a lower pressure (e.g., than in step 720). Chamber 40 may be pumped down to any pressure between about 100 milliTorr-100 Torr in this step. For example, if the chamber is pumped down to a pressure of 100 Torr in step 720, in step 740, the reduced volume of the chamber may be pumped down to any pressure lower than 100 Torr (e.g., 50 Torr). In some embodiments, in step 740, the chamber may be pumped down to a pressure between about 1-10 Torr.

In step 750, any desired thermal processing of wafer 10 may be performed. Any high temperature process may be carried out in step 750 with the heat for the process provided by lamps 82 of lamp assembly 80. For example, if the thermal process in step 750 involves curing a polymer coating on the top surface of wafer 10, lamps 82 of lamp assembly 80 may be activated to heat wafer 10 to the desired curing temperature (e.g., at the desired ramp rate) for curing the polymer. As another example, if the thermal process in step 750 involves reflowing solder bumps 12 (see FIG. 2) on wafer 10, control system 200 of oven 100 may control lamp assembly 80 to subject the solder bumps 12 to the reflow profile (e.g., the exemplary reflow profile of FIG. 3) of the solder. To subject wafer 10 to, for example, the solder reflow profile of FIG. 3, control system 200 may activate lamps 82 and/or control the power to lamps 82 to heat wafer 10 in accordance with this reflow profile based on signals from thermocouples or pyrometers in chamber 40. In some embodiments, in step 750, spindle 44 may be rotate wafer 10 to evenly heat the top surface of wafer10.

In some embodiments, a chemical vapor (e.g., formic acid vapor) may also be directed into the reduced enclosed volume of chamber 40 during step 750. For example, the chemical vapor may be directed into the enclosed volume during selected stages of the reflow profile. Rotating wafer 10 (by rotating spindle 44) may ensure that the entire top surface of wafer is evenly exposed and coated with the chemical vapor. As will be described in more detail later, the chemical vapor may be delivered into chamber 40 via a chemical delivery tube 90. In some embodiments, inert gas (e.g., nitrogen) may also be admitted into chamber 40 during some stages of the thermal processing. Inert gas may be admitted into chamber, for example, via gas inlet ports 74 on side wall 52 of chamber 40. In some embodiments, during step 750, chamber 40 may be evacuated (e.g., using vacuum pump 140 of FIGS. 9A-9B) during some stages of the thermal processing to remove excess vapor from the enclosed volume of chamber 40.

In step 760, the enclosed volume of chamber 40 may be vented to atmosphere. In some embodiments, inert gas (e.g., nitrogen) may also be directed into the enclosed volume of chamber 40 during this step, for example, to cool wafer 10. In step 770, the sealing door 48 may be moved to its lower position such that the enclosed volume of chamber 40 is increased and wafer 10 is accessible via inlet port 42. In some embodiments, the inert gas may continue to flow (e.g., via ports 74) into the increased enclosed volume of chamber 40 during this step to cool the wafer. After wafer 10 is cooled to the desired temperature, the wafer may be removed from chamber 40 via the inlet port 42 in step 780.

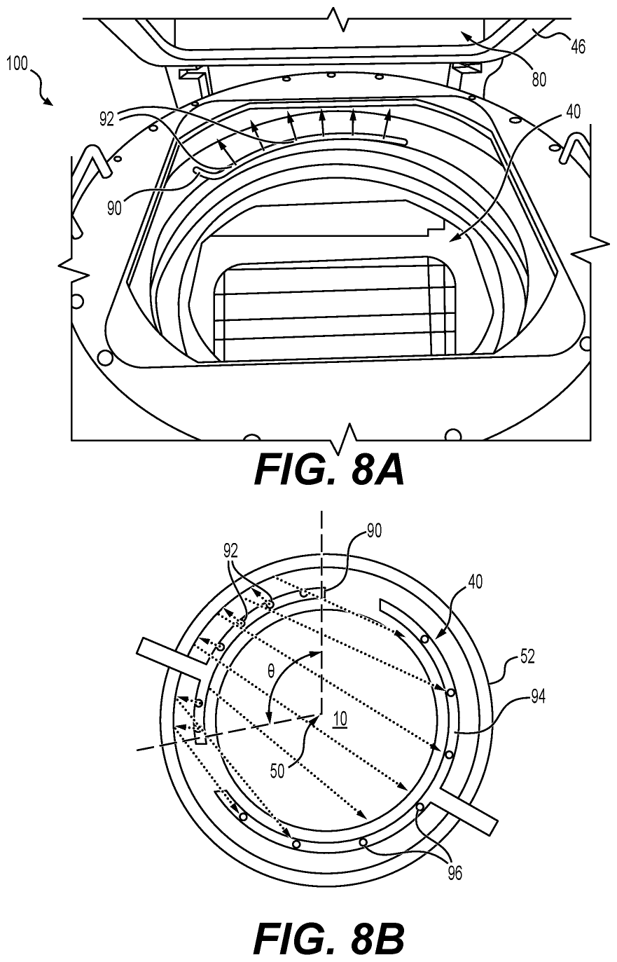

As explained previously, during some thermal processes carried out in step 750, a chemical vapor (e.g., formic acid vapor) or another process gas (e.g., a chemical in gaseous form) may injected into the enclosed volume of chamber 40 via a chemical delivery tube 90. FIG. 8A illustrates a perspective view of a portion of an exemplary oven 100 with a chemical delivery tube 90 positioned in chamber 40. In general, chemical delivery tube 90 may have a shape configured to discharge the chemical vapor or gas substantially uniformly on wafer 10. Chemical delivery tube 90 may have multiple nozzles or ports 92 to dispense the gas into chamber 40. In some embodiments, the multiple ports 92 may be arranged to dispense the gas in a generally upward direction (e.g., towards lid 46). In some embodiments, ports 92 may be arranged to direct the gas generally sideways towards the side wall 52 of chamber 40 away from wafer 10 positioned in chamber 40. The gas exiting these ports 92 may reflect off the side wall and flow over wafer 10. In some embodiments, the multiple ports 92 may be arranged to dispense the gas sideways towards wafer 10. Any number (2-20) of ports 92 may be provided on tube 90.

FIG. 8B is a schematic top view of chamber showing an exemplary chemical delivery tube 90 positioned radially outwards of the wafer positioned in the chamber. In some embodiments, as illustrated in FIG. 8A, chemical delivery tube 90 may be shaped like an arc extending circumferentially along a portion of the side wall of chamber 40. Multiple nozzles 92 may be dispersed along the length of the arc-shaped tube 90. As used herein, arc-shaped tube refers to a tube or pipe that has a curved shape resembling the form of an arc. In some embodiments, as illustrated in FIG. 8B, the arc-shaped chemical delivery tube 90 may be positioned radially outwards of the wafer 10. In other words, chemical delivery tube 90 may be an arc-shaped tube with gas-discharge ports that extends circumferentially between the perimeter of wafer 10 and the side wall 52 of chamber 40. As illustrated in FIG. 8B, the arc-shaped chemical delivery tube 90 may generally form a sector of a circle positioned radially between the perimeter of wafer 10 and the side wall 52 of chamber 40. In other words, the arc-shaped tube's curved shape may generally follow the boundary of a sector (or portion) of a circle. That is, the shape of the arc-shaped tube shares similarities with the geometric characteristics of a circular sector but may not precisely match its form. The sector angle θ, which defines the arc length or extent of the arc-shaped tube 90, may be any value. As used herein, and as illustrated in FIG. 8B, sector angle θ is the angle between two lines originating from central axis 50 (or the center of wafer 10) and extending to the two outer edges of the arc-shaped tube 90. In some embodiments, the length of chemical delivery tube 90 may be such that the sector angle θ is between about 70-120°, or between about 80-100°. In some embodiments, the length of tube 90 may be such that the sector angle θ is about 90°.

In some embodiments, as illustrated in FIG. 5B, the vertical position of chemical delivery tube 90 in chamber 40 may be such that, when sealing door 48 is positioned at its upper (or second) position, tube 90 is positioned adjacent to, or alongside, wafer 10 on spindle 44. In some embodiments, the vertical position of tube 90 in chamber 40 may be substantially equal to the vertical position of wafer 10 in chamber 40 when sealing door 48 is positioned at its upper position. In other words, the distance between tube 90 and the underside of lamp assembly 80 (or lid 46) may be substantially the same as the distance between the top surface of wafer 10 and the underside of lamp assembly 80 (or lid 46) when sealing door 48 is positioned at its upper position. Dispersing chemical vapor into chamber 40 through ports 92 of an arc-shaped chemical delivery tube 90 positioned adjacent to the wafer may enable a laminar flow of the vapor over the wafer surface and assist in treating solder bumps in all areas of wafer 10 substantially uniformly.

In some embodiments, as illustrated in FIG. 8B, chamber 40 may also include a chemical removal tube 94 with multiple exit ports 96 positioned diametrically across from chemical delivery tube 90. Chemical removal tube 94 may also be an arc-shaped tube extending circumferentially between the perimeter of wafer 10 and the side wall 52 of chamber 40. Similar to the arc-shaped chemical delivery tube 90, the chemical removal tube 94 may also generally form a sector of a circle having any sector angle. The vertical position of removal tube 94 in chamber 40 may be substantially equal to the vertical position of delivery tube 90 in chamber 40. A chemical vapor discharged or admitted into chamber 40 through ports 92 of chemical delivery tube 90 may treat the surface of wafer 10 during step 750 (of process 700 of FIG. 7) and be evacuated or removed from chamber 40 through ports 96 of chemical removal tube 94. In some embodiments, chemical removal tube 94 may be eliminated and the chemical vapor may be removed from chamber 40 through ports (e.g., ports 74, see FIG. 6) positioned on side wall 52 of chamber 40.

It should be noted that, although chemical delivery tube 90 is described as being used to deliver a chemical vapor into chamber 40, this is only exemplary. In general, chemical delivery tube 90 may be used to discharge any gas (or gaseous chemical) into the enclosed volume of chamber 40. The type of gas or vapor discharged into chamber 40 depends upon the type of thermal processing being performed in step 750 (in method 700 of FIG. 7). As illustrated in FIG. 9A, chemical delivery tube 90 may be fluidly connected to a gas (or chemical vapor) supply 110 that contains (e.g., a tank) or generates (e.g., a device such as a bubbler that produces) the gas or vapor being directed into chamber 40. The gas or vapor from gas supply 110 may be directed or admitted into chamber through the ports 92 of chemical delivery tube 90.

As also illustrated in FIG. 9A, ports 96 of chemical removal tube 94 (or the ports 74 (see FIG. 6) on the side wall 52 of chamber 40 that removes the vapor or gas from chamber 40) may be connected to a vacuum pump 140. Vacuum pump 140 may be activated (e.g., by control system 200) to remove the gas or vapor from chamber 40 and pump down chamber 40 to a sub-atmospheric pressure. In some embodiments, as illustrated in FIG. 9A, chamber 40 may be fluidly connected to vacuum pump 140 through an isolation valve 120 and a throttle valve 130. Isolation valve 120 may allow controlled start and stop of the vacuum process. It may be closed to isolate chamber 40 from vacuum pump 140 to enable maintenance, repairs, or adjustments without affecting the entire system. When vacuum pump 140 is not in operation, isolation valve 120 may prevent backflow of gases or contaminants into chamber 40 and assist in maintaining the desired vacuum level and cleanliness of chamber 40. Throttle valve 130 may allow for controlled regulation of gas flow into vacuum pump 140 and assist in regulating pumping speed and optimizing the vacuum level within chamber 40. Control system 200 may adjust the opening of throttle valve 130 to control the pressure within chamber 40.

In some embodiments, as illustrated in FIG. 9B, the gas removal connection between chamber 40 and vacuum pump 140 may include a bypass line 150 with a second isolation valve 160 and a regulator 170. Regulator 170 may control the flow of gas through bypass line 150 and allow for fine-tuning and controlling the flow of gas independent of isolation valve 120. The bypass line 150 may provide flexibility in adjusting the gas flow independently of the main line and may be useful in processes where precise control over the gas flow rate is required. The bypass line 150 may also assist in preventing overloading of vacuum pump 140 by providing an alternative path for gas to flow. The isolation valve160 in the bypass line 150 may allow for controlled activation or deactivation of the bypass line 150. It can be closed to force gas flow through the main line or opened to allow gas to bypass the main isolation valve 120. In other words, the bypass line 150 with a regulator 170 and isolation valve 160 may add a layer of control and flexibility to the vacuum system, for example, by allowing independent adjustment of gas flow, by providing an alternative path to protect the vacuum pump, and by facilitating maintenance or adjustments without disrupting the main vacuum process.

It should be noted that an arc-shape of chemical delivery tube 90 and chemical removal tube 94 is not a requirement. In general, the shape of chemical delivery tube 90 and chemical removal tube 94 may depend on the cross-sectional shape of chamber 40. FIG. 10 is a schematic illustration of a top view of an exemplary chamber 40′ in some embodiments of oven 100. As illustrated in FIG. 10, in some embodiments, chamber 40′ may have a square or rectangular cross-sectional shape and may be used to process a rectangular or square-shaped substrate 10′. In such embodiments, chemical delivery tube 90′ may be a linear tube that extends along a side (e.g., width) of substrate 10′. Multiple ports 92 may be provided on the linear-shaped delivery tube 90′ to discharge chemical vapor into chamber 40′. Chamber 40′ may also include a linear-shaped chemical removal tube 94′ positioned opposite chemical delivery tube 90′. Multiple spaced-apart ports 96 may be provided on chemical removal tube 94′ to remove chemical vapor from chamber 40′. The vertical position of tubes 90′ and 94′ may be aligned with the vertical position of substrate 10′ as discussed above with reference to tubes 90 and 94. In some embodiments, chemical removal tube 94′ may be eliminated and ports 74 (see FIG. 6) on the side walls of chamber 40′ may be used to remove the chemical vapor from the chamber 40′.

Thus, in ovens of the current disclosure, the enclosed volume of the processing chamber may be varied and selected to be one of multiple values. In other words, the processing chamber is designed in such a way that its internal space or enclosed volume can be adjusted, and users have the flexibility to choose from different possible enclosed volume settings. The adjustment of enclosed volume may be made by users, operators, or automated systems (e.g., control system 200). This ability to select different enclosed volumes allows for the customization and adaptation of the processing chamber based on specific needs and requirements. For example, this allows the chamber to accommodate and process various numbers and/or sizes of substrates efficiently. As another example, adjusting the enclosed volume to match the task can contribute to resource efficiency since a smaller volume may require less energy (e.g., to heat) and/or resources (e.g., chemicals) compared to a larger one. The configuration of the chemical delivery tube may also increase process efficiency by uniformly distributing and treating all areas of the processed substrate(s).

The above-described embodiments of ovens 100 and process 700 are only exemplary. Many variations are possible. As a person skilled in the art would recognize, the steps of process 700 need not be performed in the order illustrated in FIG. 7. Some steps may be omitted and/or some steps added in other exemplary methods. For example, in some embodiments, lamps 82 may be activated before loading wafer into the chamber (i.e., step 710) or after moving sealing door to its upper position (step 730), etc. Persons of ordinary skill in the art would recognize and understand these possible variations to be within the scope of the present disclosure. Furthermore, although oven 100 is described in conjunction with a solder reflow process, this is only exemplary. A person of ordinary skill in the art would recognize that the oven can be used for any high temperature process on any type of substrate (e.g., wafer, organic/ceramic substrates, semiconductor packages, printed circuit board (PCB), etc.).

What is claimed is:

1. An oven, comprising:
a processing chamber having an adjustable enclosed volume, the processing chamber including a spindle configured to support a substrate;
a lamp assembly configured to heat the substrate supported on the spindle, wherein the lamp assembly includes a plurality of spaced-apart lamps; and
a sealing door that bounds one end of the processing chamber, wherein the sealing door is configured to be moved from a first position to a second position to change the enclosed volume of the processing chamber from a first volume to a second volume.

2. The oven of claim 1, wherein the second volume is between about 25%-75% of the first volume.

3. The oven of claim 1, wherein the second volume is less than 50% of the first volume.

4. The oven of claim 1, wherein the sealing door bounds a bottom end of the processing chamber, and the lamp assembly is positioned at a top end of the processing chamber.

5. The oven of claim 1, wherein the spindle is configured to rotate with the substrate about a central axis of the processing chamber.

6. The oven of claim 1, wherein the substrate is positioned closer to the lamp assembly when the sealing door is located in the second position than when the sealing door is located in the first position.

7. The oven of claim 1, further including a chemical delivery tube positioned in processing chamber, wherein the chemical delivery tube includes multiple spaced-apart ports configured to discharge a gas into the processing chamber.

8. The oven of claim 7, wherein a distance of the chemical delivery tube from a top end of the processing chamber is substantially same as the distance of the substrate from the top end when the sealing door is located in the second position.

9. The oven of claim 7, wherein the chemical delivery tube is positioned radially outwards of an outer periphery of the substrate and radially inwards of a side wall of the processing chamber.

10. The oven of claim 7, wherein the chemical delivery tube has an arc-shape and subtends a sector angle between about 70-120° about a central axis of the processing chamber.

11. The oven of claim 10, wherein the sector angle is about 90°.

12. The oven of claim 1, wherein the processing chamber includes a lid, and the lamp assembly is disposed on an underside of the lid.

13. The oven of claim 1, wherein a side wall of the processing chamber includes a substrate-inlet port configured to direct the substrate into the enclosed volume of the processing chamber.

14. The oven of claim 13, wherein the substrate-inlet port is positioned above the sealing door when the sealing door is located in the first position, and the substrate-inlet port is positioned below the sealing door when the sealing door is located in the second position.

15. An oven, comprising:
a processing chamber having an adjustable enclosed volume, the processing chamber configured to support a substrate;
a lamp assembly positioned at a top end of the processing chamber, wherein the lamp assembly includes a plurality of spaced-apart lamps configured to heat the substrate; and
a sealing door at a bottom end of the processing chamber, wherein the sealing door is configured to be moved from a first position to a second position to decrease the enclosed volume of the processing chamber from a first volume to a second volume, and wherein the second volume is between about 25%-75% of the first volume.

16. The oven of claim 15, wherein the substrate is positioned closer to the lamp assembly when the sealing door is located in the second position than when the sealing door is located in the first position.

17. The oven of claim 15, further including a chemical delivery tube positioned in processing chamber, wherein the chemical delivery tube includes multiple spaced-apart ports configured to discharge a gas into the processing chamber, and wherein a distance of the chemical delivery tube from the lamp assembly is substantially same as the distance of the substrate from the lamp assembly when the sealing door is located in the second position.

18. The oven of claim 17, wherein the chemical delivery tube has an arc-shape and is positioned radially outwards of an outer periphery of the substrate and radially inwards of a side wall of the processing chamber.

19. The oven of claim 18, wherein the chemical delivery tube subtends a sector angle between about 70-120° about a central axis of the processing chamber.

20. The oven of claim 15, wherein a side wall of the processing chamber includes a substrate-inlet port configured to direct the substrate into the enclosed volume of the processing chamber, wherein the substrate-inlet port is positioned above the sealing door when the sealing door is located in the first position, and the substrate-inlet port is positioned below the sealing door when the sealing door is located in the second position.
